(19) United States
(12) Patent Application Publication
(10) Pub. No.: US 2017/0082689 A1
(43) Pub. Date: Mar. 23, 2017

(54) SYSTEMS AND METHODS FOR PARTICLE DETECTION AND ERROR CORRECTION IN AN INTEGRATED CIRCUIT

(71) Applicant: Altera Corporation, San Jose, CA (US)

(72) Inventors: Nelson Joseph Gaspard, San Jose, CA (US); Yanzhong Xu, Santa Clara, CA (US)

(21) Appl. No.: 14/859,097

(22) Filed: Sep. 18, 2015

(51) Int. Cl. G01R 31/3181; G01R 31/28

(52) U.S. Cl. CPC G01R 31/31816; G01R 31/2872

(57) ABSTRACT

An integrated circuit for detecting and correcting error events associated with atomic particles includes error detection circuitry connected to monitoring circuitry. The error detection circuitry may include a particle sensing circuit (e.g., a diode circuit) embedded below a substrate surface of the integrated circuit, and a particle validation circuit (e.g., a sense amplifier) coupled to the particle sensing circuit through a conductive via. The particle sensing circuit may detect and collect stray charges generated by an atomic particle passing through the integrated circuit. A particle validation circuit may generate an output signal that is indicative of the particle energy of the atomic particle based on the collected stray charge by the particle sensing circuit. Monitoring circuitry may identify the particle energy based on the output signal and subsequently generate an error correction signal, which activates error correction operations in the integrated circuit.

### BACKGROUND

A Single Event Upset (SEU) is a change in state or a transient voltage pulse at sensitive nodes in integrated circuits, such as processors. SEUs occur due to high energy particle strikes on the silicon substrate of processors. Errors can occur due to an SEU if it leads to a state flip in the sequential storage elements that determine the architectural state of the processor, such as the random access memory (RAM) arrays, the Register File and the architectural-state registers. An SEU can cause the affected integrated circuit to malfunction. Integrated circuits tend to become more susceptible to SEUs as integrated circuit feature sizes decrease, which is one of the more important trends in integrated circuit fabrication.

Generally, error detection cyclic redundancy checking (EDCRC) and scrubbing circuitry is used to perform SEU detection and correction in an integrated circuit. However, such circuitry requires complex detection circuitry and power to perform the SEU detection. It also takes a long time to detect the SEUs since the EDCRC and scrubbing circuitry needs to scan the entire IC for errors. This causes the EDCRC and scrubbing circuitry to be constantly running on the IC, which may result in higher power consumption and voltage supply noises.

### SUMMARY

In accordance with the present invention, systems and methods are provided for particle detection and corresponding error correction in an integrated circuit.

It is appreciated that the present invention can be implemented in numerous ways, such as a process, an apparatus, a system, or a device. Several inventive embodiments of the present invention are described below.

An integrated circuit having a substrate and logic circuitry that includes a group of transistors formed at a surface of the substrate is disclosed. The integrated circuit includes particle sensing circuitry formed below at least one transistor of the group of transistors. The particle sensing circuitry may detect a cosmic particle that passes through the logic circuitry. The particle sensing circuit may include a diode circuit that collects charges generated by the cosmic particle. The integrated circuit further includes a particle validation circuit that generates an error detection signal in response to detecting the cosmic particle with the particle sensing circuitry. The error detection signal may indicate that an error has occurred in the integrated circuit.

An integrated circuit having a surface and at least one transistor formed at the surface is disclosed. The integrated circuit includes error detection circuitry below the surface of the integrated circuit. The error detection circuitry detects charge generated by an atomic particle that passes through the integrated circuit. The integrated circuit further includes monitoring circuitry that identifies a particle energy associated with the atomic particle and that identifies error events in the integrated circuit based on the charge detected by the error detection circuitry. The monitoring circuitry may generate an error correction signal that activates error checking circuitry to perform corrective operations on error events associated with the atomic particle in the integrated circuit.

A method of operating an integrated circuit having a substrate with a substrate surface is disclosed. The method includes detecting stray charge generated by a particle passing through the integrated circuit with a particle sensing circuit. The particle sensing circuit may be embedded below the substrate surface of the integrated circuit. The method further includes correcting an error event in the integrated circuit by determining whether a voltage perturbation associated with the detected stray charge using monitoring circuitry connected to the particle sensing circuit. The monitoring circuitry may selectively correct the error events based on the identified particle energy.

Further features of the invention, its nature and various advantages will be more apparent from the accompanying drawings and the following detailed description of the preferred embodiments.

### BRIEF DESCRIPTION OF THE DRAWINGS

FIG. 1 is a diagram of an illustrative integrated circuit in accordance with an embodiment of the present invention.

FIG. 2 is a top view diagram of an illustrative integrated circuit having multiple transistor strips in accordance with an embodiment of the present invention.

FIG. 3 is a cross section diagram of an illustrative integrated circuit region of an integrated circuit in accordance with an embodiment of the present invention.

FIG. 4 is an illustrative circuit of an integrated circuit having error detection circuitry in accordance with an embodiment of the present invention.

FIG. 5 is a flow chart of illustrative steps for detecting and correcting error event in an integrated circuit in accordance with an embodiment of the present invention.

### DETAILED DESCRIPTION

The embodiments provided herein include systems and methods for atomic particle detection and error correction in an integrated circuit.

It will be obvious, however, to one skilled in the art, that the present exemplary embodiments may be practiced without some or all of these specific details. In other instances, well-known operations have not been described in detail in order not to obscure unnecessarily the present embodiments.

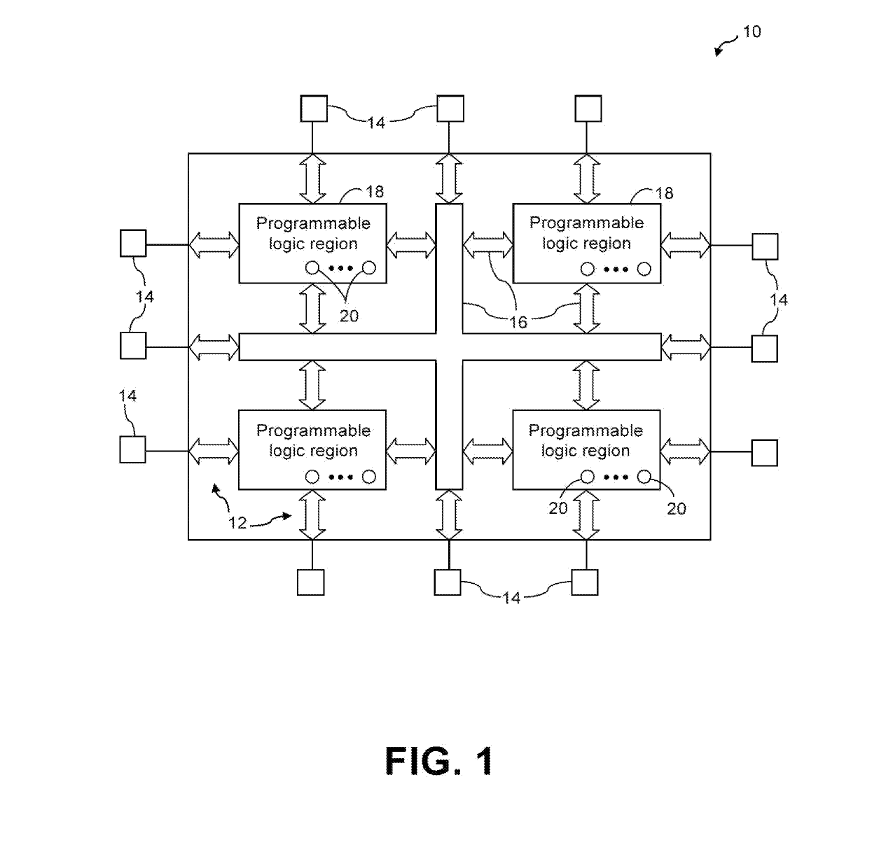

FIG. 1 is a diagram of an illustrative integrated circuit 10 in accordance with an embodiment of the present invention. Integrated circuit 10 has input-output (IO) circuitry 12 for driving signals off of integrated circuit 10 and for receiving signals from other circuits or devices via IO pins 14. Interconnection resources 16 such as global and local vertical and horizontal conductive lines and busses may be used to route signals on integrated circuit 10. Interconnection resources 16 include fixed interconnects (conductive lines) and programmable interconnects (e.g., programmable connections between respective fixed interconnects). The programmable interconnects associated with interconnection resources 16 may be considered to be a part of programmable logic regions 18.

Integrated circuit 10 contains volatile memory elements 20 that can be loaded with configuration data (also called programming data) using IO pins 14 and IO circuitry 12. Once loaded, the memory elements each provide a corresponding static control output signal that controls the state of an associated logic component in programmable logic 18. If desired, memory elements 20 may be used in SRAM-type memory arrays (e.g., to store data for processing circuitry during operation of integrated circuit 10).

Each memory element 20 may be formed from a number of transistors configured to form a bistable circuit. With one suitable approach, complementary metal-oxide-semiconductor (CMOS) integrated circuit technology is used to form the memory elements 20, so CMOS-based memory element implementations are described herein as an example. If desired, other integrated circuit technologies may be used to form the memory elements and the integrated circuit in which the memory elements are used to form memory arrays.

The memory elements may be loaded from an external erasable-programmable read-only memory and control chip or other suitable data source via IO pins 14 and IO circuitry 12. Loaded CRAM memory elements 20 may provide static control signals that are applied to the terminals (e.g., gates) of circuit elements (e.g., metal-oxide-semiconductor transistors) in programmable logic 18 to control those elements (e.g., to turn certain transistors on or off) and thereby configure the logic in programmable logic 18. The circuit elements may be transistors such as pass transistors, parts of multiplexers, look-up tables, logic arrays, AND, OR, NAND, and NOR logic gates, etc.

The memory elements 20 may be arranged in an array pattern. During programming operations, the array of memory elements may be provided with configuration data by a user (e.g., a logic designer). Once loaded with configuration data, the memory elements 20 selectively control portions of the circuitry in the programmable logic 18 and thereby customize its functions so that it will operate as desired.

The circuitry of integrated circuit 10 may be organized using any suitable architecture. As an example, the logic of integrated circuit 10 may be organized in a series of rows and columns of larger programmable logic regions each of which contains multiple smaller logic regions. The logic resources of integrated circuit 10 may be interconnected by interconnection resources 16 such as associated vertical and horizontal conductors. These conductors may include global conductive lines that span substantially all of integrated circuit 10, fractional lines such as half-lines or quarter lines that span part of integrated circuit 10, staggered lines of a particular length (e.g., sufficient to interconnect several logic areas), smaller local lines, or any other suitable interconnection resource arrangement. If desired, the logic of integrated circuit 10 may be arranged in more levels or layers in which multiple large regions are interconnected to form still larger portions of logic. Still other device arrangements may use logic that is not arranged in rows and columns.

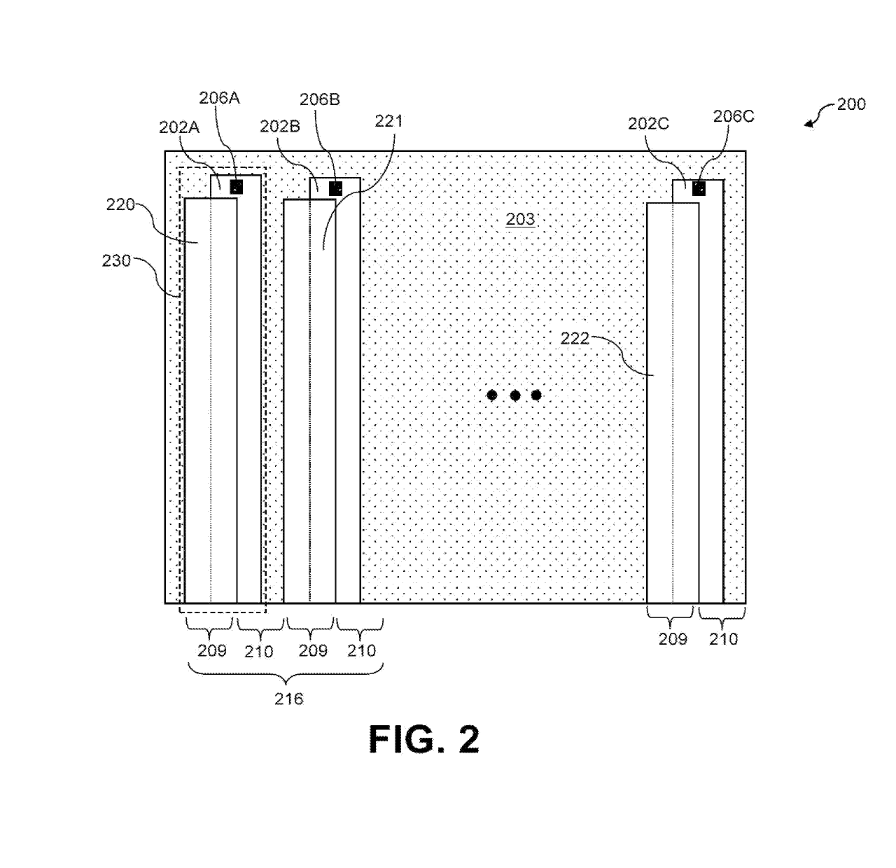

When memory elements 20 are arranged in an array, horizontal and vertical conductors and associated loading circuitry may be used to load the memory elements with configuration data. Any suitable memory array architecture may be used to load an array of memory elements 20. One suitable arrangement is shown in FIG. 2. FIG. 2 is a top view diagram of integrated circuit 200 having multiple transistor strips in accordance with an embodiment of the present invention. Integrated circuit 200 includes multiple strips (or columns) of transistors (e.g., transistor strips 220, 221, and 222) formed on a semiconductor substrate (e.g., substrate 203). For the purpose of simplifying the description of an example of the invention, only three transistor strips (e.g., transistor strips 220, 221, and 222) are shown in FIG. 2. Transistor strips 220, 221, and 222 may be part of an array of memory elements 20 of FIG. 1. It should be noted that a typical memory array might, as an example, have thousands or millions of memory elements 20 arranged in hundreds or thousands or rows and columns. N-type well regions (e.g., N-well regions 209) and P-type well regions (e.g., P-well regions 210) may be placed so that they are directly abutting active devices such as transistors (not shown) within each transistor strip.

Memory cells that include memory elements such as memory elements 20 are prone to errors such as single event upsets (SEUs) that are sometimes also referred to as soft errors. An SEU occurs when a charged particle causes a transient voltage spike, which results in a change of state of the memory element. The charged particle may be due to natural radiation that is present in substrate of the integrated circuit and die packaging or generated in the substrate by cosmic rays or other atomic particles (e.g., alpha particles, neutron, and protons). One of the ways to detect the charged particle in the integrated circuit is by forming a particle sensing circuit (e.g., particle sensing circuits 202A, 202B, and 202C) under each transistor strip. As shown in FIG. 2, particle sensing circuits 202A, 202B, and 202C are illustrated as blanket implants or stripes formed near the surface of substrate 203. Particle sensing circuits 202A, 202B, and 202C may be extended along and below N-well regions 209 of transistor strips 220, 221, and 222, respectively. In one embodiment, particle sensing circuits 202A, 202B, and 202C may collect particle charge deposited by the charged particle within the respective transistor strips 220, 221, and 222. For example, particle sensing circuits 202A, 202B, and 202C may be diode circuits. In another embodiment, the use of multiple particle sensing circuits in integrated circuit 200 may allow the location of the particle strike to be identified.

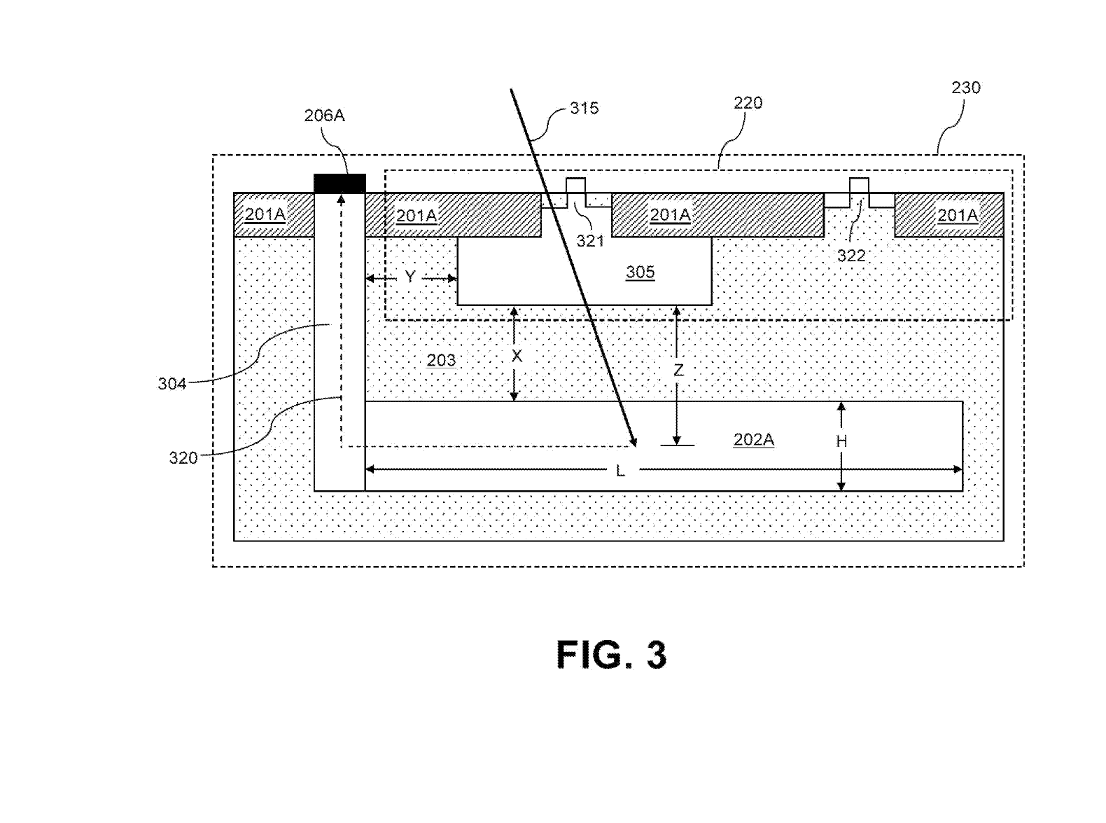

Accordingly, each particle sensing circuit 202A, 202B, and 202C may be connected to a corresponding particle validation circuit (e.g., particle validation circuits 206A, 206B, and 206C). In one embodiment, a particle validation circuit may sense the particle charge collected by a particle sensing circuit and generate an error detection signal that triggers error correction operations in integrated circuit 200. For example, particle validation circuits 206A, 206B, 206C may be sensor circuits. A more detailed description of transistor strip 220, particle sensing circuit 202A, and particle validation circuit 206A is described below with reference to integrated circuit region 230 of FIG. 3.

FIG. 3 is a cross sectional diagram of an illustrative integrated circuit region 230 of integrated circuit 200 of FIG. 2 (e.g., with a more detailed representation of transistor strip 220, particle sensing circuit 202A, and particle validation circuit 206A). As shown, a strip of transistors (e.g., transistor strip 220) is formed in substrate 203. In one embodiment, a combination of N-channel metal oxide semiconductor (NMOS) and P-channel metal oxide semiconductor (PMOS) transistors may be present in transistor strip 220. As an example, one PMOS transistor (e.g., transistor 321) may be formed in an N-type well region (e.g., N-well 305), and one NMOS transistor (e.g., transistor 322) may be formed in a P-type well region (not shown in FIG. 3 but represented by P-well 210 of FIG. 2, for example). In practice there may be one or more additional N-wells and P-wells. Further, there may be many (e.g., tens, hundreds, or thousands) of transistors formed in each well. To prevent electrical current leaking between adjacent transistors 321 and 322, shallow trench isolation (STI) region 201A may be formed on the surface of substrate 203 to isolate transistors 321 and 322 from each other.

As shown, transistors 321 and 322 may be subjected to an atomic particle (e.g., cosmic particle) strike, as indicated by arrow 315. The atomic particle may interfere with charges held within sensitive nodes of the transistors in the integrated circuit, thereby affecting the corresponding logic states. When high energy atomic particles strike a sensitive node region, the particles can cause a bit in the memory cell to change states or flip. These soft errors, which are also known as single event upsets (SEUs), generally affect storage elements, such as memory, latches and registers.

In order to detect the occurrence and location of the atomic particle strike (or single event) in the integrated circuit, a stray charge of the atomic particle may be collected and analyzed. To do so, a particle sensing circuit may be formed near the sensitive nodes of the transistors to collect the charge deposited by the atomic particle. As shown, particle sensing circuit 202A of height H is implanted below N-well 305 of a depth Z in substrate 203. In one embodiment, depth Z may correspond to a peak doping depth. Depth Z may be, for example, about 1.5 μm. Height H may be, for example, about 1 micrometer (μm). Particle sensing circuit 202A may also extend substantially in a horizontal plane in substrate 203, from N-well 305 of transistor 321 to the P-well region (not shown) of transistor 322. In one example, particle sensing circuit 202A may be a diode circuit.

To ensure that the atomic particle charge is electrically isolated from interfering signals (e.g., switching noises) in other wells, P-type implant regions may be formed surrounding N-well 305. A P-type implant region is represented by substrate 203 in FIG. 3. For example, a P-type implant region of height X is created between the bottom surface of N-well region 305 and the top surface of particle sensing circuitry 202A. Height X may be, for example, 1 μm. Accordingly, another P-type implant region of width Y may be created between boundaries of N-well 305 and conductive via 304. Width Y may be, for example, 1 μm. The configuration of the P-type implant regions also ensures that no electrical conductivity is present within substrate 203.

In one embodiment, the size of the particle sensing circuit may influence a detectable voltage perturbation from deposited charge of the atomic particle due to junction capacitance (i.e., capacitive effect at a junction of the particle sensing circuit). Larger particle sensing circuits may have greater junction capacitance than smaller particle sensing circuits, which may lead to smaller voltage perturbations from an atomic particle strike than when smaller particle sensing circuits are used. In an exemplary embodiment, to detect a neutron particle, a particle sensing circuit having a size of, for example, 1 μm in both width and height (denoted by H) and 13 millimeters (mm) in length (denoted by L), will have a voltage perturbation of about 30 millivolts (mV). In contrast, a particle sensing circuit having a size of, for example, 1 μm in both width and height (denoted by H) and 1 millimeters (mm) in length (denoted by L), will have a voltage perturbation of about 360 mV.

In another exemplary embodiment, to detect an alpha particle, a particle sensing circuit having a size of, for example, 1 μm in both width and height (denoted by H) and 0.04 millimeters (mm) in length (denoted by L), will have a voltage perturbation of about 30 millivolts (mV).

In contrast, a particle sensing circuit having a size of, for example, 1 μm in both width and height (denoted by H) and 0.01 millimeters (mm) in length (denoted by L), will have a voltage perturbation of about 110 mV.

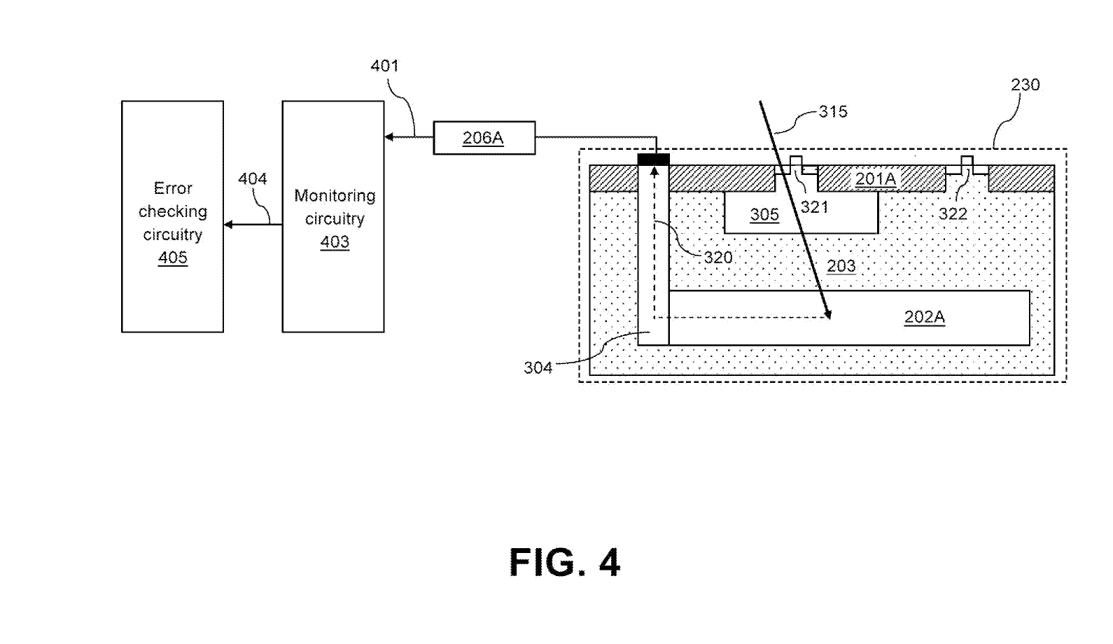

The voltage perturbation from the deposited charge of the atomic particle can be detected by particle sensing circuit 202A as indicated by arrow 320. For example, particle validation circuit 206A may include a sensor circuit, such as a sense amplifier. Particle validation circuit 206A may generate an output signal (which may also be referred to as a sensor output), which is described later in FIG. 4, based on the collected charges. The resultant output signal may trigger error correction operations associated with the atomic particle strike in the integrated circuit.

FIG. 4 is an illustrative integrated circuit having error detection circuitry in accordance with an embodiment of the present invention. The integrated circuit may be similar to integrated circuit 200 of FIG. 2. For the purpose of simplifying the description of the present invention, only a portion (e.g., integrated circuit region 230 of FIGS. 2 and 3) of the integrated circuit 200 is illustrated. Discussion of components already shown in integrated circuit region 230 (e.g., substrate 203, transistors 321 and 322, N-well 305, substrate 203, conductive via 304, and shallow trench isolation (STI) region 201A) and described above will not be repeated.

As shown in FIG. 4, the error detection circuitry includes a particle sensing circuit (e.g., particle sensing circuit 202A) coupled to an associated particle validation circuit (e.g., particle validation circuit 206A). Particle sensing circuit 202A and particle validation circuit 206A may collectively detect soft error events caused by atomic particle strikes that occur in the integrated circuit. Generally, the soft error events (“single event upsets” or SEUs) occur when a high-energy atomic particle strikes the critical circuitry (e.g., transistors 321 and 322 of FIG. 3) in an integrated circuit. A resulting transient voltage spike may be generated, which may cause a change of state (e.g., flipping of bits) of storage elements, such as memory elements 20 of FIG. 1, in the integrated circuit.

Because transistors 321 and 322 can be potentially struck by a high-energy atomic particle, particle sensing circuit 202A may be provided in substrate 203 to detect the particle strike. As an example, assume that a particle strike occurs within transistor strip 210 (as indicated by arrow 315). A stray charge produced by the atomic particle may be deposited within sensitive nodes (e.g., N-well 305 of transistor 321) of transistor strip 210. In this scenario, particle sensing circuit 202A, which is implanted below transistors 321 and 322 in substrate 203, may collect the deposited charge from N-well 305.

Accordingly, particle validation circuit 206A may validate the collected charge from particle sensing circuit 202A by detecting a voltage perturbation from the deposited charge of the atomic particle as indicated by arrow 320. It should be appreciated that particle validation circuit 206A may be implemented either internally or externally to integrated circuit 200 of FIG. 2. For clarity and ease of illustration, particle validation circuit 206A is depicted outside of integrated circuit region 230. A resultant voltage perturbation output (e.g., output signal 401) may be generated by particle validation circuit 206A based on the detected voltage perturbation from the collected charge. In one embodiment, the voltage perturbation output may represent particle energy of the atomic particle that strikes the sensitive nodes in the integrated circuit. Subsequently, output signal 401 is transmitted to monitoring circuitry 403.

In one embodiment, monitoring circuitry 403 may monitor a status of output signal 401 to identify a particle energy associated with the atomic particle and to identify error events in the integrated circuit. For example, monitoring circuitry 403 may include a polling circuit. In an embodiment, monitoring circuitry 403 may poll output signal 401 to determine whether a predetermined metric has changed, for example by comparing voltage perturbation output (e.g., output signal 401) to a predetermined voltage threshold. When the voltage perturbation output exceeds a predetermined threshold value, monitoring circuit 403 may generate an error correction signal (e.g., error correction signal 404) to error checking circuitry 405.

In general, error checking circuitry 405 may perform error detection and correction operations on the configuration RAM (CRAM) cells (e.g., memory elements 20 of FIG. 1) on integrated circuit 200 for soft errors (i.e., bit flips). For example, error checking circuitry 405 may include error detection cyclic redundancy checking (EDCRC) and scrubbing circuitry. In accordance with an embodiment of the invention, the operational frequency of error checking circuitry 405 can be reduced or turned off prior to the detection of atomic particle charge so as to reduce power consumption and voltage supply noises in the integrated circuit. Error checking circuitry 405 can be activated by error correction signal 404 to perform error correction operations on error events associated with the atomic particle strike in the integrated circuit.

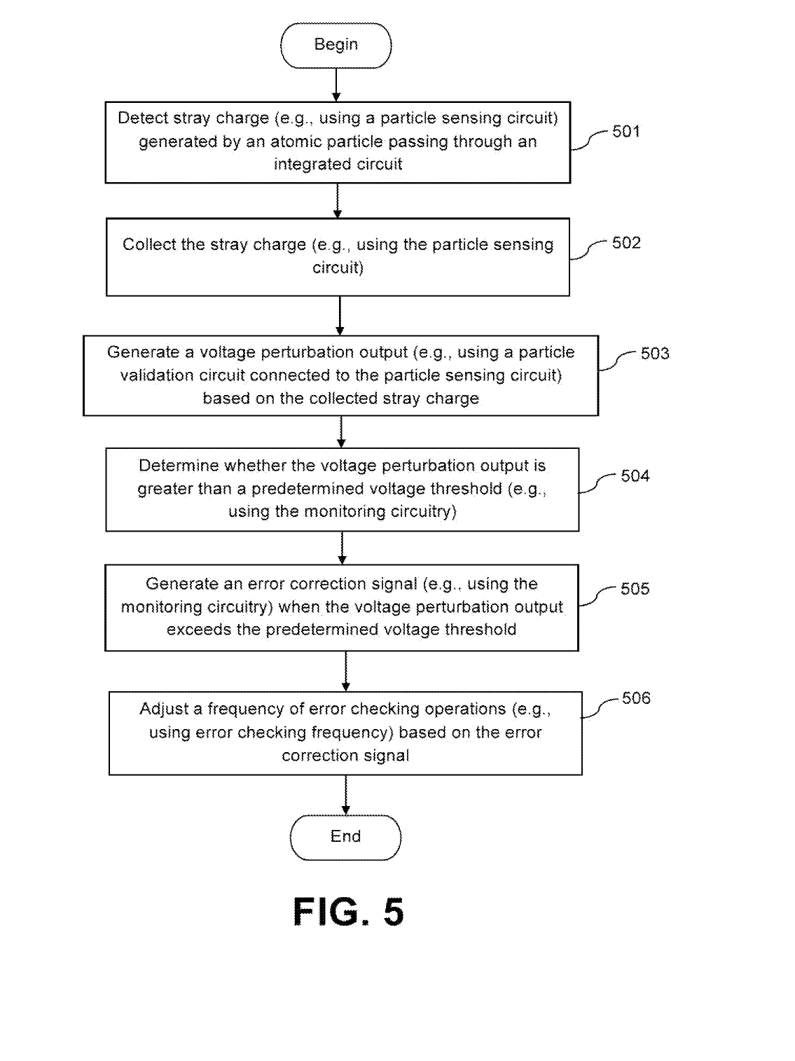

Illustrative steps involved in detecting and correcting soft error effects on an integrated circuit are shown in FIG. 5. It should be noted that FIGS. 3 and 4 will be used as exemplary embodiments to describe the present invention below.

During an atomic particle strike (as indicated by arrow 315 of FIGS. 3 and 4), the atomic particle may deposit a stray charge within the sensitive nodes in the integrated circuit (e.g., integrated circuit 200 of FIG. 2). At step 501, the stray charge can be detected using a particle sensing circuit (e.g., particle sensing circuit 202A of FIG. 2). For example, the particle sensing circuit may be a diode circuit. In one embodiment, multiple particle sensing circuits (e.g., particle sensing circuits 202B and 202C of FIG. 2) can be used to identify a location of the atomic particle strike in the integrated circuit.

The deposited stray charge of the atomic particle is then collected by the particle sensing circuit at step 502. A particle validation circuit (e.g., particle validation circuit 206A of FIGS. 3 and 4) connected to the particle sensing circuit may detect a voltage perturbation based on the collected charge and subsequently generate a voltage perturbation output at step 503. In one embodiment, the voltage perturbation output (e.g., output signal 401 of FIG. 4) is indicative of the particle energy of the atomic particle that strikes the integrated circuit.

At step 504, it is determined whether the voltage perturbation output is greater than a predetermined voltage threshold using the monitoring circuitry. As shown in FIG. 4, monitoring circuitry 403 may poll the voltage perturbation output (e.g., output signal 401) to determine whether a predetermined metric has changed. The polling may be conducted by comparing voltage perturbation output (e.g., output signal 401) to a predetermined voltage threshold. When the voltage perturbation output exceeds a predetermined threshold value, monitoring circuit 403 may generate an error correction signal (e.g., error correction signal 404) at step 505.

At step 506, a frequency of error checking operations is adjusted using error checking circuitry (e.g., error checking circuitry 405 of FIG. 4) based on the error correction signal. In one embodiment, the operational frequency of the error checking circuitry can be reduced or turned off prior to the detection of the stray charge generated by the atomic particle so as to reduce power consumption and voltage supply noises in the integrated circuit. The error checking circuitry can be activated by the error correction signal to perform error correction operations on error events associated with the atomic particle strike in the integrated circuit.

The methods and apparatus described herein may be incorporated into any suitable circuit. For example, the methods and apparatus may be incorporated into numerous types of devices such as microprocessors or other integrated circuits. Exemplary integrated circuits include programmable array logic (PAL), programmable logic arrays (PLAs), field programmable logic arrays (FPGAs), electrically programmable logic devices (EPLDs), electrically erasable programmable logic devices (EEPLDs), logic cell arrays (LCAs), field programmable gate arrays (FPGAs), application specific standard products (ASSPs), application specific integrated circuits (ASICs), just to name a few.

The programmable logic device described in one or more embodiments herein may be part of a data processing system that includes one or more of the following components: a processor; memory; IO circuitry; and peripheral devices. The data processing system can be used in a wide variety of applications, such as computer networking, data networking, instrumentation, video processing, digital signal processing, or any suitable other application where the advantage of using programmable or re-programmable logic is desirable. The programmable logic device can be used to perform a variety of different logic functions. For example, the programmable logic device can be configured as a processor or controller that works in cooperation with a system processor. The programmable logic device may also be used as an arbiter for arbitrating access to a shared resource in the data processing system. In yet another example, the programmable logic device can be configured as an interface between a processor and one of the other components in the system. In one embodiment, the programmable logic device may be one of the family of devices owned by the assignee.

Although the method operations were described in a specific order, it should be understood that other operations may be performed in between described operations, described operations may be adjusted so that they occur at slightly different times or described operations may be distributed in a system which allows the occurrence of the processing operations at various intervals associated with the processing, as long as the processing of the overlay operations are performed in a desired way.

The foregoing is merely illustrative of the principles of this invention and various modifications can be made by those skilled in the art without departing from the scope and spirit of the invention.

What is claimed is:

1. An integrated circuit having a substrate and logic circuitry that includes a plurality of transistors formed at a surface of the substrate, the integrated circuit comprising:
particle sensing circuitry formed within the substrate below at least one transistor of the plurality of transistors, wherein the particle sensing circuit is operable to detect a cosmic particle that passes through the logic circuitry; and
a particle validation circuit that generates a detection signal in response to detecting the cosmic particle with the particle sensing circuitry.

2. The integrated circuit defined in claim 1, wherein the detection signal is an error detection signal.

3. The integrated circuit defined in claim 1, wherein the particle sensing circuit comprises a diode circuit that collects a charge generated by the cosmic particle.

4. The integrated circuit defined in claim 3, wherein the diode circuit is implanted in the substrate below an N-well region of the plurality of transistors.

5. The integrated circuit defined in claim 1, wherein the particle sensing circuit is formed within a P-well region of the plurality of transistors.

6. The integrated circuit defined in claim 1, wherein the particle sensing circuit is electrically coupled to the particle validation circuit through a conductive via.

7. The integrated circuit defined in claim 1, wherein the particle validation circuit comprises a sense amplifier.

8. The integrated circuit defined in claim 1, wherein the particle sensing circuit is one of a plurality of particle sensing circuits, each of which is arranged to detect a location of the cosmic particle within the integrated circuit.

9. The integrated circuit defined in claim 8, wherein the particle validation circuit is one of a plurality of particle validation circuits, wherein each of the plurality of particle validation circuits is coupled to a corresponding one of the plurality of particle sensing circuits through a corresponding conductive via.

10. An integrated circuit having a surface and at least one transistor formed at the surface, the integrated circuit comprising:
error detection circuitry below the surface of the integrated circuit, wherein the error detection circuitry detects a charge generated by an atomic particle that passes through the integrated circuit; and
monitoring circuitry that identifies a particle energy associated with the atomic particle and that identifies error events in the integrated circuit based on the charge detected by the error detection circuitry, wherein the monitoring circuitry selectively corrects the error events based on the identified particle energy.

11. The integrated circuit defined in claim 10, wherein the error detection circuitry comprises a diode circuit that detects the charge by collecting a stray charge deposited in the integrated circuit by the atomic particle.

12. The integrated circuit defined in claim 11, wherein the diode circuit is implanted at a depth of about 1 micrometer to 1.5 micrometer from an N-well region of the at least one transistor.

13. The integrated circuit defined in claim 11, wherein the error detection circuitry further comprises a sensor circuit coupled to the diode circuit, wherein the sensor circuit outputs a sensor output that is indicative of the particle energy of the atomic particle.

14. The integrated circuit defined in claim 13, wherein the monitoring circuitry comprises polling circuitry that generates an error correction signal based on the sensor output when a magnitude of the sensor output exceeds a predetermined threshold value.

15. The integrated circuit defined in claim 14, further comprising:
error correcting circuitry that selectively adjusts a frequency of error checking operations for the error events based on the error correction signal.

16. A method of operating an integrated circuit having a substrate with a substrate surface, the method comprising:
with a particle sensing circuit embedded below the substrate surface of the integrated circuit, detecting a stray charge generated by a particle passing through the integrated circuit; and
with monitoring circuitry coupled to the particle sensing circuit, correcting an error event in the integrated circuit by determining whether a voltage perturbation associated with the stray charge detected by the particle sensing circuit is greater than a predetermined voltage threshold.

17. The method defined in claim 16, further comprising:
with the particle sensing circuit, collecting the stray charge generated by the particle and passing the collected stray charge to the monitoring circuitry.

18. The method defined in claim 17, further comprising:
with a sensor circuit coupled to the particle sensing circuit, generating a voltage perturbation output based on the stray charge collected by the particle sensing circuit from the particle.

19. The method defined in claim 18, further comprising:
with the monitoring circuitry, receiving the voltage perturbation output; and
with the monitoring circuitry, comparing the voltage perturbation output to the predetermined voltage threshold.

20. The method defined in claim 19, further comprising:
with the monitoring circuit, generating an error correction signal when the voltage perturbation output exceeds the predetermined voltage threshold.

21. The method defined in claim 20, further comprising:
with error checking circuitry, receiving the error correction signal; and
with the error checking circuitry, activating at least one error correction operation in the integrated circuit based on the error correction signal.

22. The method defined in claim 21, further comprising:
with the error checking circuitry, reducing a frequency of the at least one error checking operation prior to detecting the stray charge generated by the particle passing through the integrated circuit.
